(19) United States
(12) Patent Application Publication
(10) Pub. No.: US 2016/0087577 A1
(43) Pub. Date: Mar. 24, 2016

(54) FLEXIBLE SOLAR CELLS COMPRISING THICK AND THIN ABSORBER REGIONS

(71) Applicants: INTERNATIONAL BUSINESS MACHINES CORPORATION, ARMONK, NY (US); KING ABDULAZIZ CITY FOR SCIENCE AND TECHNOLOGY, RIYADH (SA)

(72) Inventors: ABDULRAHMAN ALBADRI, RIYADH (SA); STEPHEN BEDELL, YORKTOWN HEIGHTS, NY (US); NING LI, YORKTOWN HEIGHTS, NY (US); DEVENDRA SADANA, YORKTOWN HEIGHTS, NY (US); KATHERINE L. SAENGER, OSSINING, NY (US); ABDELMAJID SALHI, RIYADH (SA); DAVOOD SHAHRJERDI, YORKTOWN HEIGHTS, NY (US)

(21) Appl. No.: 14/495,559

(22) Filed: Sep. 24, 2014

(51) Int. Cl. H01L 31/042; H01L 31/0232; H01L 31/0216; H01L 31/18; H01L 31/0352; H01L 31/0224

(52) U.S. Cl. CPC H02S 30/00; H01L 31/03529; H01L 31/022433; H01L 31/02168; H01L 31/18; H01L 31/1868; H01L 31/02327

(57) ABSTRACT

A solar cell includes a p-type semiconductor substrate including a plurality of thin absorption regions and a plurality of thick absorption regions. The plurality of thin absorption regions and the plurality of thick absorption regions are coplanar on a bottom side thereof. An n-type semiconductor layer is disposed over a top side of the p-type semiconductor substrate. The n-type semiconductor layer has a substantially uniform thickness. Metallurgy is disposed on top of the n-type semiconductor layer. The plurality of thin absorption regions are sufficiently thin to render the semiconductor substrate flexible.

### TECHNICAL FIELD

The present disclosure relates to solar cells and, more specifically, to flexible solar cells comprising thick and thin absorber regions.

### DISCUSSION OF THE RELATED ART

Solar cells, which are able to use energy from light to generate electricity, are increasingly an important source for renewable power. Solar cells are frequently formed from a semiconductor material such as silicon. Light is absorbed by the silicon which causes excitation of the electrons of the silicon. Some of these excited electrons then travel though the solar cell until it reaches an electrode, thereby causing current to flow.

Solar cells are rigid and this rigidity limits the ability of the solar cells to be applied to surfaces that are to be exposed to sunlight. The semiconductor region of solar cells also tend to be relatively thick and this thickness increases cost of manufacture, which can have a large impact on the practicality of using solar cells as an alternative to conventional power sources.

### SUMMARY

A solar cell includes a p-type semiconductor substrate including a plurality of thin absorption regions and a plurality of thick absorption regions. The plurality of thin absorption regions and the plurality of thick absorption regions are coplanar on a bottom side thereof. An n-type semiconductor layer is disposed over a top side of the p-type semiconductor substrate. The n-type semiconductor layer has a substantially uniform thickness. Metallurgy is disposed on top of the n-type semiconductor layer. The plurality of thin absorption regions are sufficiently thin to render the semiconductor substrate flexible.

The thick absorption regions may each be 20-70 microns thick and the thin absorption regions may each be 0-20 microns thick.

The thick absorption regions may each be at least five times as thick as each of the thin absorption regions.

A method for fabricating a solar cell includes disposing an adhesion or seed layer on a bottom surface of a semiconductor absorption substrate. A stressor layer is applied onto the adhesion layer or seed layer. The stressor layer has an intrinsic tensile stress and a pattern of thick and thin regions. The semiconductor absorption substrate is spalled such that a pattern of thick and thin absorption regions corresponding to the pattern of thick and thin stressor regions are formed therefrom. The stressor layer is removed from the bottom surface of the spalled semiconductor absorption substrate. A backing layer is applied to the bottom surface of the spalled semiconductor absorption substrate. A semiconductor emitter layer is disposed over a top surface of the spalled semiconductor absorption substrate. The semiconductor emitter layer has a substantially uniform thickness. Metallurgy is applied over the semiconductor layer.

The semiconductor absorption substrate may include a p-type semiconductor and the semiconductor emitter layer may include an n-type semiconductor.

The metallurgy may be a plurality of metallic fingers or bus contacts.

The thick absorption regions may each be 20-70 microns thick and the thin absorption regions may each be 0-20 microns thick.

The thick absorption regions may each be at least five times as thick as each of the thin absorption regions.

The plurality of thin absorption regions may be sufficiently thin to render the semiconductor substrate flexible.

A passivation layer may be disposed over the semiconductor emitter layer.

An antireflective coating may be disposed over the semiconductor emitter layer.

The step of applying the backing layer to the bottom surface of the spalled semiconductor absorption substrate may include disposing an aluminum layer to the bottom surface of the spalled semiconductor absorption substrate.

The aluminum layer may be disposed in blanket contact with the bottom surface of the spalled semiconductor absorption substrate.

The aluminum layer may be in contact with the bottom surface of the spalled semiconductor absorption substrate between a pattern of dielectric reflectors.

A back-surface-field layer may be disposed between the bottom surface of the spalled semiconductor absorption substrate and the aluminum layer.

An insulating tape carrier may be disposed under the aluminum layer.

Applying a stressor layer onto the adhesion layer or seed layer may includes, sputtering a first nickel layer on the adhesion layer or seed layer, plating a second nickel layer on the sputtered nickel layer or seed layer, disposing a resist pattern on the second nickel layer or seed layer, plating a third nickel layer on the second nickel layer through the resist pattern, and removing the resist pattern.

The stressor layer may have a tensile stress of greater than 100 megapascals.

A method for forming a mixed thickness substrate includes disposing an adhesion layer or a seed layer on a bottom surface of a semiconductor substrate. A first nickel layer is sputtered on the adhesion layer or seed layer. A second nickel layer is plated on the sputtered nickel layer or seed layer. A resist pattern is disposed on the second nickel layer or seed layer. A third nickel layer is plated on the second nickel layer through the resist pattern. The resist pattern is removed. The semiconductor substrate is spalled such that a pattern of thick and thin regions corresponding to the arrangement of the third nickel layer disposed through the resist pattern are formed therefrom.

The plurality of thin absorption regions may be sufficiently thin to render the semiconductor substrate flexible.

### BRIEF DESCRIPTION OF THE DRAWINGS

A more complete appreciation of the present disclosure and many of the attendant aspects thereof will be readily obtained as the same becomes better understood by reference to the following detailed description when considered in connection with the accompanying drawings, wherein:

FIGS. 1A-1E illustrate an arrangement of back surface options that may be applied to mixed thickness solar cells in accordance with exemplary embodiments of the present invention;

FIGS. 2A-2E illustrate a mixed thickness absorption layer arranged in a plurality of different solar cell configurations in accordance with exemplary embodiments of the present invention;

FIGS. 3A-3D illustrate exemplary geometries for a two-thickness cell in accordance with exemplary embodiments of the present invention;

FIGS. 4A-4H are diagrams illustrating a method for fabricating solar cells having multi thickness absorption regions in accordance with exemplary embodiments of the present invention;

FIGS. 5A and 5B are pictures illustrating a semiconductor substrate with thick and thin nickel stressor layers deposited thereon and the semiconductor substrate after spalling in accordance with exemplary embodiments of the present invention;

FIG. 6 is a diagram illustrating two-thickness patterned stressor layers in accordance with exemplary embodiments of the present invention;

FIGS. 7A-7E are diagrams illustrating two-thickness patterned stressor layers in which an aluminum adhesion-etch stop layer and a nickel stack may be used as a seed layer for plating in accordance with exemplary embodiments of the present invention;

FIGS. 8A-8B are diagrams illustrating dual function stressor/seed layers utilizing a blanket seed layer in accordance with exemplary embodiments of the present invention; and

FIGS. 9A-9B are diagrams illustrating dual function stressor/seed layers utilizing a patterned seed layer in accordance with exemplary embodiments of the present invention.

### DETAILED DESCRIPTION OF THE DRAWINGS

In describing exemplary embodiments of the present disclosure illustrated in the drawings, specific terminology is employed for sake of clarity. However, the present disclosure is not intended to be limited to the specific terminology so selected, and it is to be understood that each specific element includes all technical equivalents which operate in a similar manner.

Exemplary embodiments of the present invention provide solar cells that are flexible and methods for fabricating flexible solar cells. The solar cells so described may also utilize less material and may be less expensive to manufacture. Exemplary embodiments of the present invention may utilize a spalling technique to provide a relatively thin semiconductor layer in the solar cell. The semiconductor layer may be thin enough to render the resulting solar cell substantially flexible.

Spalling is a technique used to thin a substrate in which a metallic adhesion layer may be deposited on a substrate. A spall-inducing stressor layer may then be applied to the adhesion layer. The stressor layer may have a relatively high tensile stress. The thickness and measure of tensile stress of the stressor layer may be selected to produce the desired to induce the desired spalling phenomenon. The tensile stress of the stress layer may make the substrate prone to separate at a particular depth that may be controlled by the thickness and tensile stress of the stress layer that was applied. Then, spalling may be induced by beginning to sheer the substrate along the desired depth, for example, by starting a peeling at a corner of the wafer, or by quickly changing the temperature of the substrate, for example, by submerging the substrate in liquid nitrogen. The substrate will then split cleanly at the depth that has been made prone to splitting at by the presence of the stress layer.

Exemplary embodiments of the present invention may use spalling to thin the silicon layer of the solar cell to the point at which it is flexible. However, as silicon has a relatively poor absorption of light in the near infra red (IR) range, thinning the silicon layer may produce solar cells that are less efficient at generating electricity from light than solar cells using relatively thick silicon layers. Moreover, using spalling to create a thin silicon layer may result in cracking, especially where the area being spalled is relative large. It may not be practical to tile together multiple small regions of spalled silicon due to the high cost of managing the multiple independent pieces.

Exemplary embodiments of the present invention utilize a modified spalling technique to produce a solar cell having an absorber layer, for example, a semiconductor layer, that is made up of a pattern of thick and thin absorption regions. The thick absorption regions may provide adequate power generating efficiency while the thin regions absorption regions may provide flexibility. The semiconductor layer, so spalled, may still remain a single contiguous layer thereby simplifying subsequent processing and handling thereof.

As described above, spalling is a technique used to cleanly break a substrate along a desired plane. Exemplary embodiments of the present invention provide a modified approach to spalling that does not break the substrate along a single plane, but rather breaks the substrate in such a way as to produce a pattern of thick and thin regions. Techniques for performing this modified spalling and the resulting structures are described in detail below.

As discussed above, solar cells, in accordance with exemplary embodiments of the present invention, may include a plurality of thick absorber regions and a plurality of thin absorber regions. The thick regions may be approximately 20-70 microns thick. However, the upper limit need not be material and the thick regions may be greater than or equal to 20 microns thick. For example, the thick regions may be at least 30 microns thick, at least 40 microns thick, or at least 50 microns thick.

In contrast, the thin absorber regions may be approximately 1-20 microns thick. However, the lower limit need not be material and the thin regions may be less than or equal to 20 microns thick. For example, the thin regions may be no greater than 20 microns thick, no greater than 10 microns thick, or no greater than 5 microns thick. According to some exemplary embodiments of the present invention, the thin regions may be substantially zero microns thick, for example, there might not be any absorber at all in the thin absorber regions. However, even in these cases, the solar cell may remain a single contiguous unit held together by other structural layers and would not be divided into a set of separate structures.

While the above-described thickness ranges for the thick and thin absorption regions may at least partially overlap, for example, at 20 microns; exemplary embodiments of the present invention may have thick regions that are at least twice as thick as the thin regions. For example, the thick regions may be at least 5 times as thick as the thin regions, may be at least 15 times as thick as the thin regions, may be at least 30 times as thick as the thin regions, or may be at least 75 times as thick as the thin regions. According to some exemplary embodiments of the present invention, the thick regions may be between 10 and 100 times as thick as the thin regions.

Moreover, the absorber may include multiple thick regions and/or multiple thin regions, each of which has a substantially different thickness. For example, a first thin region may be a fixed thickness no greater than 10 microns thick while a second thin region may be zero microns thick.

Exemplary embodiments of the present invention may provide a range of different geometric configurations for thick and thin absorption regions, several examples of which are discussed in detail below. Solar cells utilizing these arrangements may be referred to herein as mixed thickness solar cells.

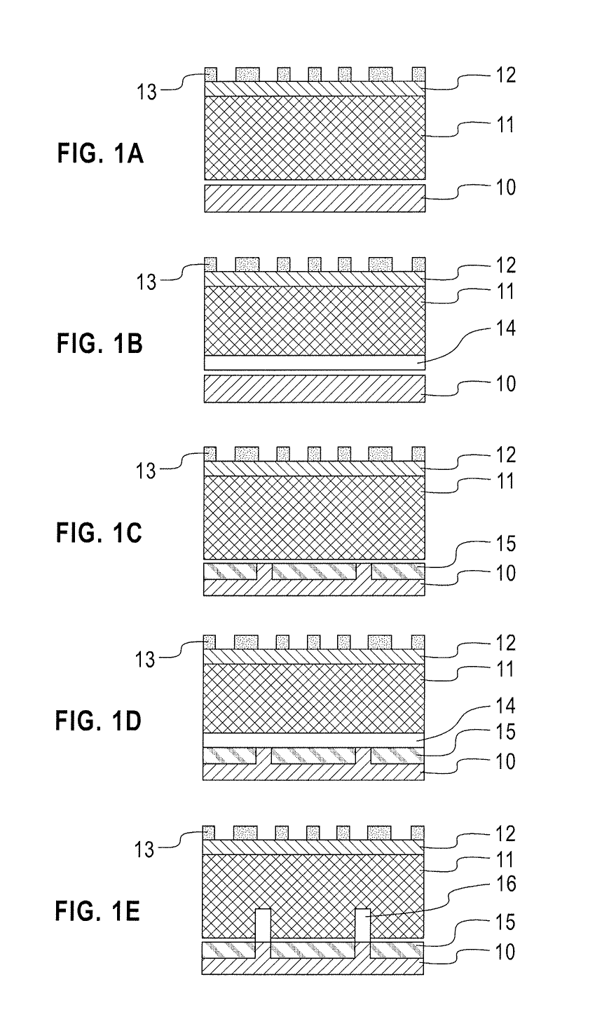

Mixed thickness solar cells may be made from mixed thickness solar cell substrates with any of the features known to be used for single-thickness, thick solar cells. A solar cell back surface may include a blanket conductive layer contact. A solar cell front surface may include an emitter (or double/selective emitter), passivation and/or antireflection coatings, and metallic finger and bus contacts. FIGS. 1A-1E illustrate an arrangement of back surface options that may be applied to mixed thickness solar cells in accordance with exemplary embodiments of the present invention. Each of these arrangements may be suitable for textured and non-textured surfaces alike. For the purposes of providing a simplified description, the solar cells are depicted as having a single emitter on the front surface, although other arrangements are possible.

In particular, FIG. 1A illustrates a solar cell having a metallized back surface 10, for example, including aluminum. This configuration has no back-surface-field (BSF) and may have a blanket contact. The absorption layer may include a p-type semiconductor layer 11 disposed on the metallized back surface 10. An “n+”-type semiconductor layer 12 may be disposed on the p-type semiconductor layer 11. Finger/bus metallurgy 13 may be disposed on the “n+”-type semiconductor layer 12.

FIG. 1B illustrates a solar cell having a blanket contact and a BSF. A “p++”-type semiconductor layer 14 may be disposed over the aluminum layer 10. The remainder of the structure may be comparable to that discussed above. FIG. 1C illustrates a solar cell having localized contact and no BSF. Here, the aluminum layer 10 may include a patterned dialectic reflector 15 disposed therein. FIG. 1D illustrates a solar cell having localized contact and a BSF. FIG. 1E illustrates a solar cell having localized contact and a localized BSF 16. It is to be understood that the mixed thickness absorption layer may be applied to any of these configurations shown.

While only certain solar cell layers have been shown for the purposes of simplifying the disclosure, it is to be understood that many other designs and material layers may be utilized on these flexible mixed-thickness solar cell substrates, such as Sanyo-type HIT (heterojunction with intrinsic thin layer) cells and materials, interdigitated back contact cells, and emitter wrap through cells (EWT).

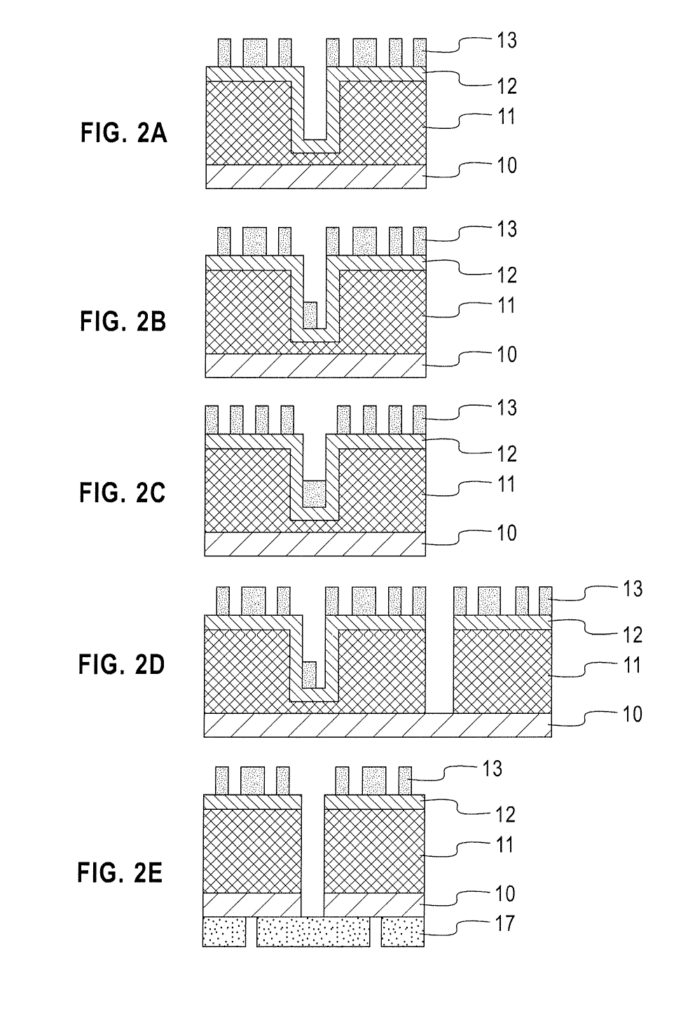

FIGS. 2A-2E illustrate a mixed thickness absorption layer arranged in a plurality of different solar cell configurations in accordance with exemplary embodiments of the present invention. In particular, FIG. 2A illustrates an arrangement in which the p-type semiconductor layer 11 has a first thick region (left), a second thick region (right), and a thin region therebetween. As is the case if FIG. 1A, there is blanket contact and no BSF. The finger/bus metallurgy 13 is disposed entirely over the thick absorption regions and not over the thin absorption region.

FIG. 2B illustrates a mixed thickness solar cell having blanket contact and no BSF, similar to what is shown in FIG. 2A. However here, the finger/bus metallurgy 13 is not aligned to the substrate topography and as a result, the finger/bus metallurgy 13 is disposed over the thick and thin absorption regions.

FIG. 2C illustrates a mixed thickness solar cell having blanket contact and no BSF. However, here, the finger/bus metallurgy 13 is aligned to the substrate topography such that the finger/bus metallurgy 13 is disposed intermittently over the thick absorption regions and fully covers the thin absorption regions. In this case, the finger/bus metallurgy 13 may be thicker over the thin absorption regions than over the thick absorption regions.

FIG. 2D illustrates a mixed thickness solar cell having blanket contact and no BSF. Here, from left to right, there is a thick absorption region, a thin absorption region, a thick absorption region, a zero-thickness absorption region, and a thick absorption region. Here, the finger/bus metallurgy 13 is disposed over the thick and thin absorption regions but is not disposed over the zero-thickness absorption region. Substrates including “zero-thickness” absorber regions over a conductive backing layer such as those shown in FIG. 2D may be useful for cases in which a the back contact is not easily accessible, for example, where the back contact layer is covered with an insulating tape.

FIG. 2E illustrates a mixed thickness solar cell having blanket contact and no BSF. From left to right there is a thick absorption region, a zero-thickness absorption region, and a thick absorption region. Unlike the examples described above, here the thick absorption regions are electrically isolated by the absence of the aluminum layer 10 under the zero-thickness absorption regions. An insulating carrier tape 17, which may be an optional component for each structure shown above, is illustrated as providing structural connectivity for the thick absorption regions.

The optimum arrangement of the different thickness regions with respect to the finger/bus wiring and any other structures in the cell may depend on the requirements and priorities of the solar cell being manufactured.

As described above, mixed thickness solar cells in accordance with exemplary embodiments of the present invention may utilize a modified spalling technique in which a semiconductor substrate is converted into a pattern of thick and thin absorption regions. This may be accomplished, for example, by depositing a thin adhesion layer on the semiconductor substrate. The thin adhesion layer may be metallic, but need not have tensile stress. According to one example, the thin adhesion layer may be a titanium layer having a thickness of between 10 and 50 nanometers, for example, 40 nanometers. The stressor layer may be deposited on the adhesion layer. The stressor layer may also be metallic. The stressor layer may have a desired degree of tensile stress that may be relatively large. According to one exemplary embodiment of the present invention, the stressor layer may include a combination of sputtered and plated nickel with a combined thickness of up to 40 microns and a tensile stress of between 100 and 1000 megapascals (MPa), for example, between 200 and 500 MPa, for example between 300 and 400 MPa. A stressor layer so described may be used in conjunction with a silicon absorption layer to spall a layer of silicon that is about twice the thickness of the nickel stressor layer. A backing layer, which may include tapes, may be applied to the stressor layer either before or after semiconductor spalling to help preserve the mechanical integrity of the spalled layer and/or to serve as handles for the structure. As described above, spalling may be induced by starting a peel at the wafer edge or immersing in liquid nitrogen. At some stage after spalling, some or all of the high-stress stressor layer is removed by a process such as wet etching.

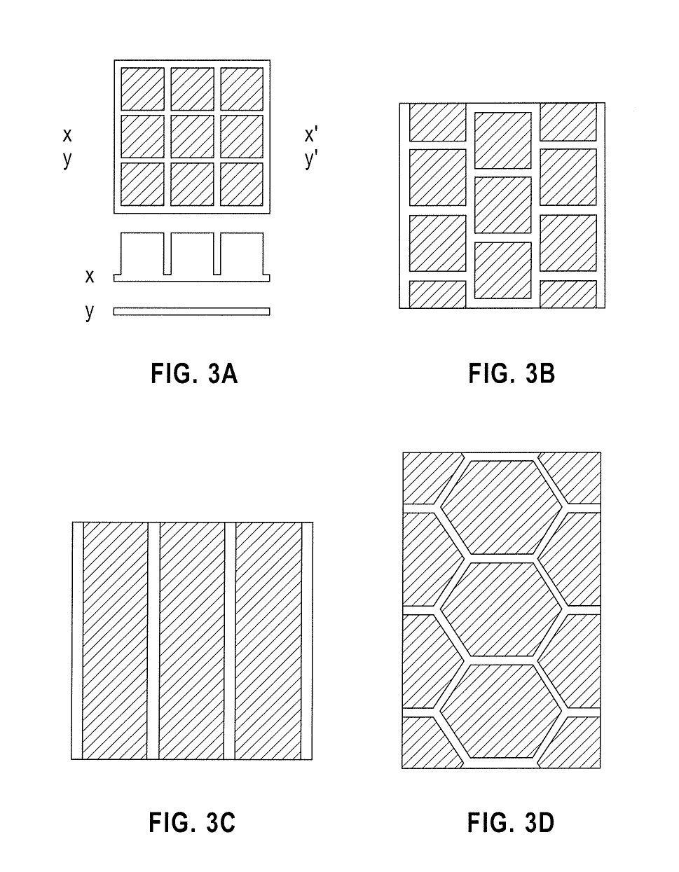

As stated above, the mixed thickness substrates for flexible solar cells may include well-defined pluralities of thick and thin absorber region features. More generally, the mixed thickness substrates for flexible solar cells may include well-defined pluralities of absorber region features with each plurality containing features with a characteristic thickness. The optimum values for the number of pluralities, the relative area of each plurality, and the thickness, surface texture, size, and shape of the absorber region features comprising each plurality may depend on the specific application. FIGS. 3A-3D illustrate exemplary geometries for a two-thickness cell. In particular, FIG. 3A shows aligned rectangular or square mesas (in top and cross-section view). FIG. 3B shows partially staggered rectangular or square mesas (in cross-section view). FIG. 3C shows a rib structure (in cross-section view). FIG. 3D shows fully staggered hexagon mesas (in cross-section view). Many other geometries are possible.

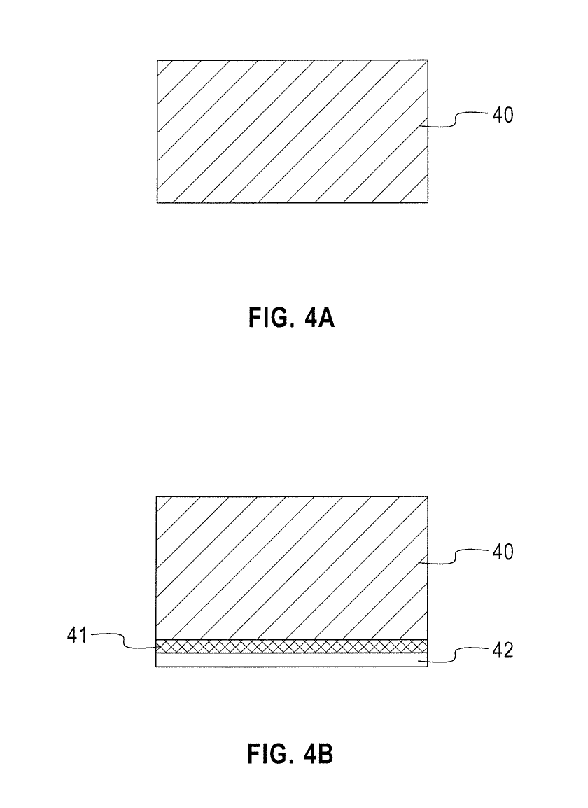

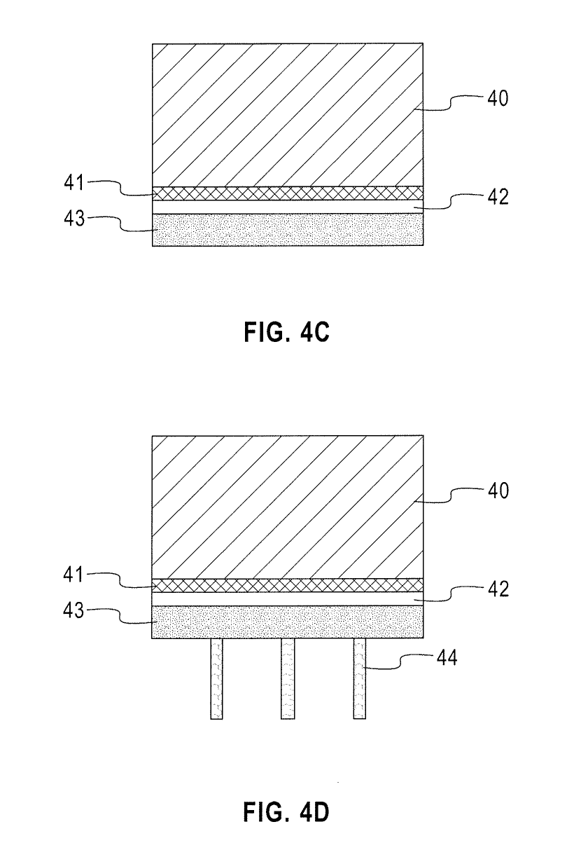

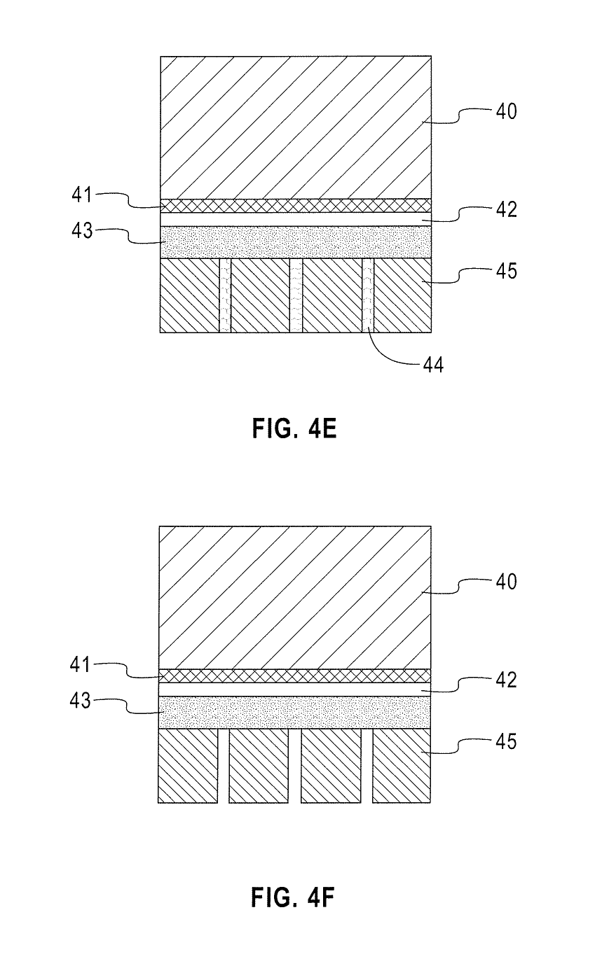

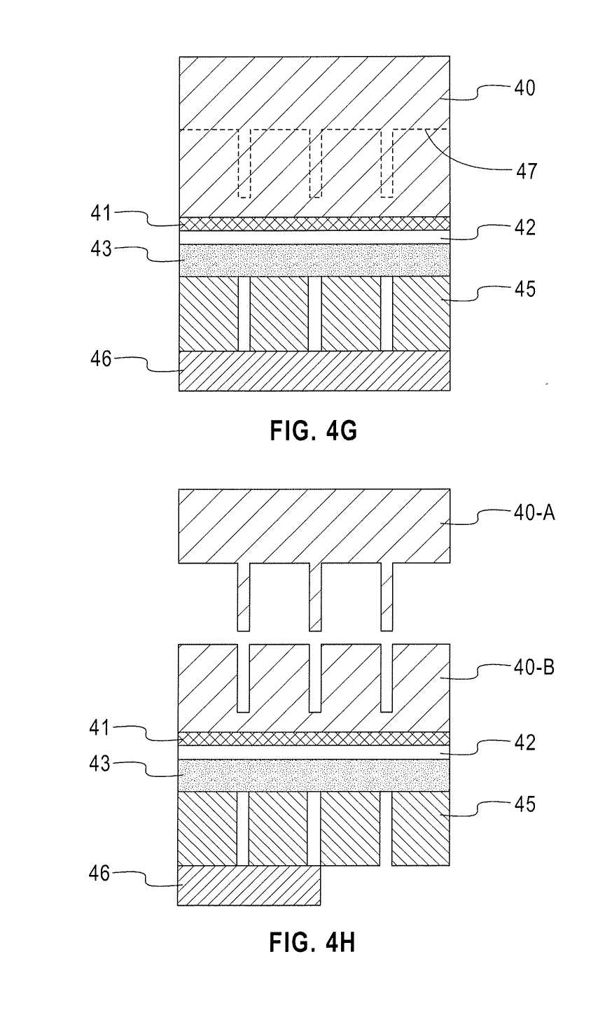

FIGS. 4A-4H are diagrams illustrating a method for fabricating solar cells having multi thickness absorption regions in accordance with exemplary embodiments of the present invention. As shown in FIG. 4A, a semiconductor substrate 40 may be provided. The semiconductor substrate 40 may be a polished silicon substrate. Then, as seen in FIG. 4B, an adhesion layer 41 may be disposed on the semiconductor substrate 40. The adhesion layer 41 may include titanium. A layer of sputtered nickel 42 may be provided on the adhesion layer 41. Together, the layers of titanium adhesion 41 and sputtered nickel 42 may be approximately 50 nm thick. Then, as shown in FIG. 4C, a layer of plated nickel 43 may be disposed over the sputtered nickel layer 42. The layer of plated nickel 43 may be approximately 5 microns thick.

Then, as can be seen in FIG. 4D, a pattern 44 may be formed over the plated nickel layer 43. The pattern may be formed by applying a photoresist, exposing the photoresist using a mask, and then etching the exposed photoresist. The resulting pattern may define 5 mm wide gaps separated by 0.5 mm wide walls. Alternatively, the resulting pattern may define 10 mm wide gaps separated by 1 mm wide walls. Alternatively, the resulting pattern may define 20 mm wide gaps separated by 2 mm wide walls. Other arrangements may be used.

Then, as can be seen in FIG. 4E, more plated nickel 45 may be disposed within the gaps formed by the pattern 44. The resulting plated nickel 45 rectangles may be sized and separated as defined by the pattern 44 described above.

Together, the sputtered nickel layer 42, the plated nickel layer 43 and the plated nickel rectangles 45 may form the stressor layer that has a tensile stress as described above.

As can be seen in FIG. 4F, the resist pattern 44 may be stripped. Then, as can be seen in FIG. 4G, a tape backing layer 46 may be optionally applied. The shape of the stressor layer 42, 43, and 45 may dictate the shape of the resulting spalling surface 47. Accordingly, the stepped stressor layer may result in a stepped semiconductor absorption layer.

Then spalling may be performed. The spalling may serve to fracture the semiconductor substrate 40 along the spalling surface 47, as is depicted in FIG. 4H. A top section 40-A of the semiconductor substrate 40 may be discarded and its material may be reused. The bottom section 40-B of the semiconductor substrate 40 may be used as the absorption layer of a solar cell, made flexible and effective by the pattern of thick and thin absorption regions. It is noted that the boundaries between the thick and thin regions may be sloped rather than vertical, with the lateral dimensions of the transition region depending on the thick-to-thin thickness differential and the direction of spalling with respect to the direction of the step (up or down).

As described above, in accordance with exemplary embodiments of the present invention, spalling may be used to create mixed-thickness substrate layers that include zero-thickness semiconductor regions. This can be done with the use of a two-thickness stressor layer similar to the one described above, modified so that the blanket portion of the stressor layer has a stress and thickness below the threshold for spalling. Spalling with such a stressor layers may be done using a tape backing. However, some zero-thickness regions (particularly via-shaped ones used for contacts) may be formed by starting with mixed thickness substrates having thin and thick regions and then removing the thin-thickness regions in selected areas by processes such as etching, laser scribing, etc. Both spalling and etching methods for creating zero-thickness regions may be used to create electrically isolated thick-thickness regions when the conductive layers connecting the thick-thickness regions are be removed down to the insulating (tape) backing layer, for applications in which the isolated thick-thickness cells may be connected in series (after cell fabrication) to achieve higher voltage devices.

When these spalling processes are used to form mixed thickness solar cells, at least some portion of the stressor layer may be left on the spalled semiconductor layer. In such cases, the back portion of the cell may be fabricated before the stressor layer is applied. Examples of various back cell structures that might be disposed at the solar cell back under a generic patterned stressor layer are shown and described above with reference to FIGS. 1A-1E.

Many possible materials and processes may be used to form the components of the stressor layer stack and the choice of how to arrange the stressor layer stack may be guided by reliability and cost considerations. The order in which the one or more blanket stressor layers and the one or more patterned stressor layers are formed may also be varied, and the materials of these one or more blanket and patterned stressor layers may be the same or different. While the examples described herein primarily describe how metals might be incorporated into a two-thickness stress layer stack, the stress layer stack may include materials other than metals. For example, various blanket or patterned layers may be inserted into the stress layer stack for reduced contact resistance, passivation layer modification, improved oxidation resistance, adhesion promotion, diffusion barrier function, or etch stop function. Methods of deposition include plating, physical vapor deposition (PVD) techniques such sputtering, evaporation, reactive sputtering; chemical vapor deposition (CVD), atomic layer deposition (ALD), chemical solution deposition (CSD) techniques (spray, spin-on, lamination, etc.). Methods of stressor patterning include through-mask plating, through-shadow-mask deposition, lift-off, etching through a mask, and various imprinting and/or stamping techniques. Plating, typically with a sputtered seed layer, is a preferred technique due to its low cost and compatibility with efficient-material-use through-mask plating processes. Sputtering may be higher cost but it is compatible with patterned deposition with the use of shadow masks.

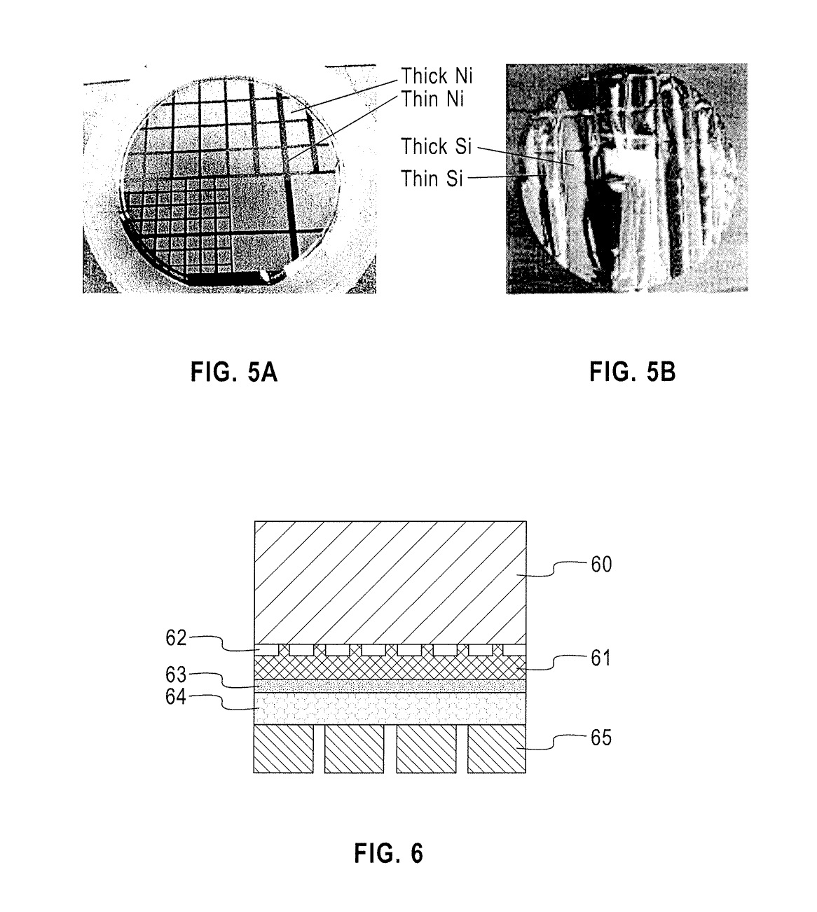

FIG. 5A is a pictures illustrating the semiconductor substrate with thick and thin nickel stressor layers deposited thereon. FIG. 5B is a picture illustrating the same semiconductor substrate after spalling, with a similar configuration of thick and thin regions.

FIGS. 6-9 show examples of various two-thickness patterned stressor layers illustrated for the case of semiconductor wafers with the patterned back surface dielectric reflector/localized contacts of FIG. 1C. In particular, FIG. 6 is a diagram illustrating the Ti/Ni example of FIG. 4, in which the stressor layer comprises a blanket sputtered Ti/Ni seed layer 63, a blanket plated nickel layer 64, and patterned features of through-mask plated nickel 65. An adhesion layer 61 including patterned dielectric reflectors 62 is used to secure the stressor layers to the semiconductor substrate 60.

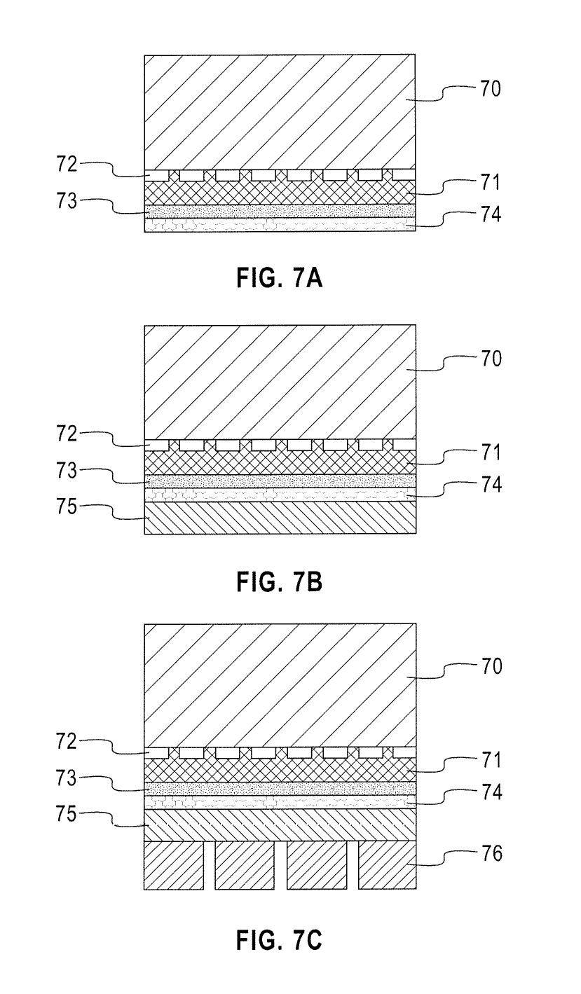

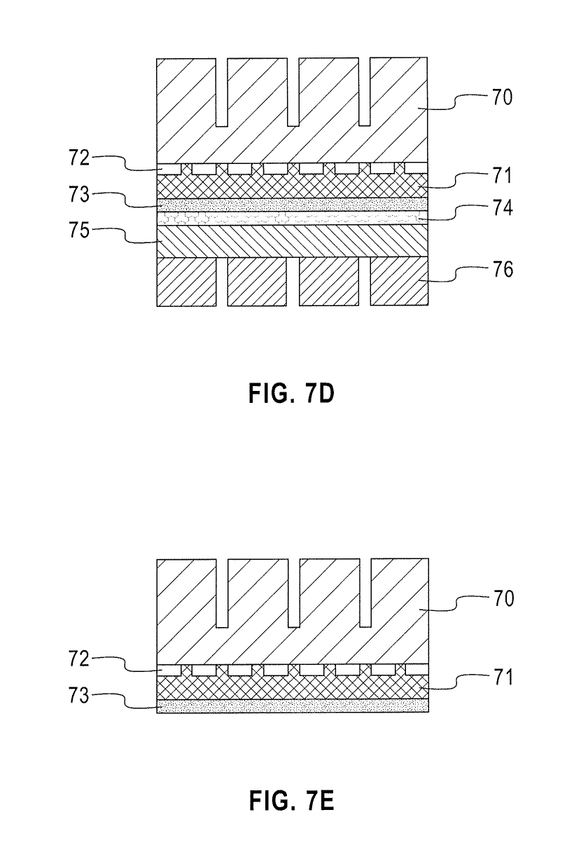

According to some exemplary embodiments of the present invention, aluminum may be used instead of titanium as the back surface metallic reflector and contact. To create a blanket aluminum that is thin enough not to interfere with spalling, an aluminum adhesion-etch stop layer and a nickel stack may be used as a seed layer for plating, as shown in FIGS. 7A-7E. The aluminum may be disposed using a forming gas anneal (FGA). If the aluminum FGA is performed before adhesion-etch stop/Ni layer deposition, the aluminum layer may be capped with an additional conductive oxidation barrier layers (e.g., TiN or Ti/TiN) prior to FGA. If the aluminum FGA is performed after adhesion-etch stop/Ni deposition (e.g., in which case the entire aluminum etch stop/Ni layer may be deposited in a single sputter deposition step and annealed together), the adhesion-etch stop layer (e.g., Ti) may include additional barriers to prevent Al—Ni interdiffusion.

An example of this process is shown in FIGS. 7A-7E. As can be seen in FIG. 7A, a seed layer including adhesion/etch-stop 73 and nickel 74 is formed on a back surface of an aluminum layer 71 that includes patterned dielectric reflectors 72. After completion of the seed layer stack and aluminum FGA, as can be seen in FIG. 7B, a blanket nickel stressor layer 75 may be plated on the sputtered nickel layer 74 Ni. As can be seen in FIG. 7C, this may be followed by through-mask plating of a patterned stressor layer 76. The sample is then spalled (optionally using a tape backing layer), as shown in FIG. 7D. To achieve the desired flexibility, the thick patterned nickel regions 76 may be removed. This may be accomplished, for example, by etching the nickel down to the etch stop layer 73, as shown in FIG. 7E.

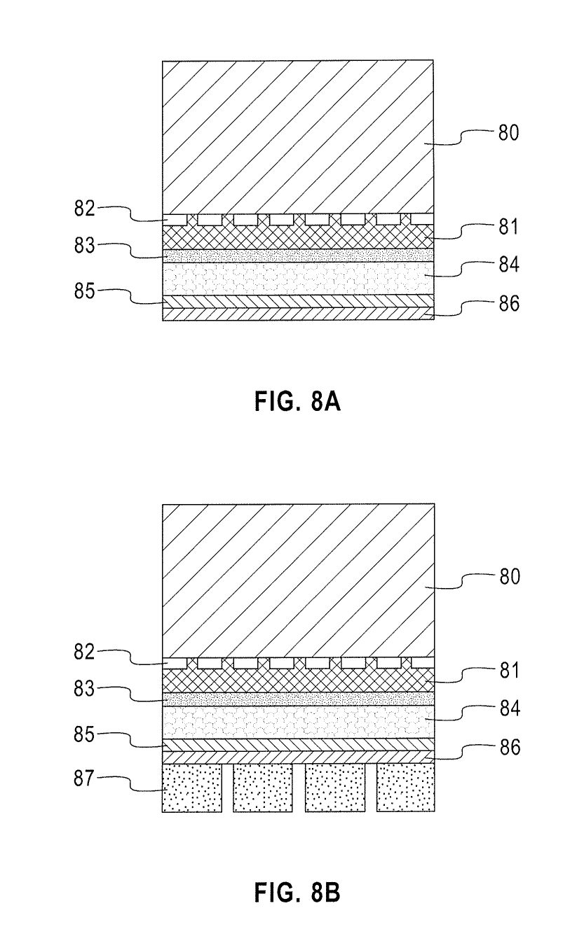

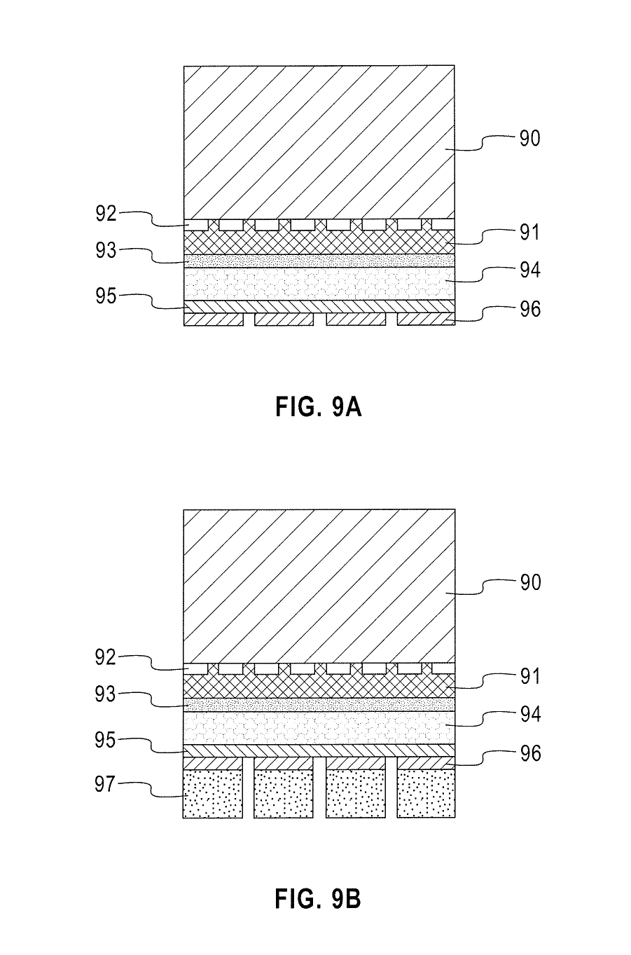

Dual function stressor/seed layers may be provided when the desired thickness of the blanket nickel stressor is thin enough to be conveniently deposited by sputtering. This stands in contrast to the cases described above where the blanket nickel stressor is a separate layer plated onto a nickel seed layer. FIGS. 8 and 9 show examples of a dual function stressor/seed layers, one utilizing a blanket seed layer (FIG. 8) and one utilizing a patterned seed layer (FIG. 9) in accordance with exemplary embodiments of the present invention.

In particular, FIG. 8A is a diagram illustrating a dual function stressor/seed layer utilizing a blanket seed layer in accordance with exemplary embodiments of the present invention. Here a semiconductor substrate 80 is covered with the aluminum layer 81 including the patterned dielectric reflector 82. An adhesion/etch-stop layer 83 is disposed on the aluminum layer 81. A first layer of sputtered blanket nickel 84 functions as a stressor layer. A second adhesion/etch-stop layer 85 is disposed on the first layer of sputtered nickel 84. A second layer of sputtered blanket nickel 86 is disposed on the second adhesion/etch-stop layer 86. The second layer of sputtered blanket nickel 86 may function as a seed layer for through-mask patterned nickel plating 87 that produces the structure of FIG. 8B. The location of the etch stop within the sputtered nickel layers is selected so that the desired thickness of nickel may be left in the structure after the topmost nickel is removed. All of these layers may be deposited in the same sputter deposition step.

FIG. 9A is a diagram illustrating a dual function stressor/seed layer utilizing a patterned seed layer in accordance with exemplary embodiments of the present invention. Like FIG. 8A, the structure of FIG. 9A includes a first layer of blanket nickel 94 functioning as a stressor layer and a second layer of nickel 96 disposed on a second adhesion/etch-stop layer 95 to function as a seed layer for patterned plating. However, in this case, the nickel seed layer 96 is sputter deposited through a shadow mask to form nickel seed features that can be selectively plated with nickel to form the structure 97 of FIG. 9B without the need for a photoresist mask. Similar to FIG. 8A, the first layer of blanket nickel 94 is disposed on a first adhesion/etch-stop layer 93, which is disposed on an aluminum layer 91 including a patterned dielectric reflector 92, which is disposed on a semiconductor substrate 90.

Exemplary embodiments described herein are illustrative, and many variations can be introduced without departing from the spirit of the disclosure or from the scope of the appended claims. For example, elements and/or features of different exemplary embodiments may be combined with each other and/or substituted for each other within the scope of this disclosure and appended claims.

1. A solar cell, comprising:
a p-type semiconductor substrate including a plurality of thin absorption regions and a plurality of thick absorption regions, wherein the plurality of thin absorption regions and the plurality of thick absorption regions are coplanar on a bottom side thereof;
an n-type semiconductor layer disposed over a top side of the p-type semiconductor substrate, the n-type semiconductor layer having a substantially uniform thickness; and
metallurgy disposed on top of the n-type semiconductor layer,
wherein the plurality of thin absorption regions are sufficiently thin to render the semiconductor substrate flexible.

2. The solar cell of claim 1, wherein the thick absorption regions are each 20-70 microns thick and the thin absorption regions are each 0-20 microns thick.

3. The solar cell of claim 1, wherein the thick absorption regions are each at least five times as thick as each of the thin absorption regions.

4. A method for fabricating a solar cell, comprising:
disposing an adhesion or seed layer on a bottom surface of a semiconductor absorption substrate;
applying a stressor layer onto the adhesion layer or seed layer, the stressor layer having an intrinsic tensile stress and having a pattern of thick and thin regions;
spalling the semiconductor absorption substrate such that a pattern of thick and thin absorption regions corresponding to the pattern of thick and thin stressor regions are formed therefrom;
removing the stressor layer from the bottom surface of the spalled semiconductor absorption substrate;
disposing a semiconductor emitter layer over a top surface of the spalled semiconductor absorption substrate, the semiconductor emitter layer having a substantially uniform thickness; and
applying metallurgy over the semiconductor emitting layer,
wherein the stressor layer is configured to spall the pattern of thick and thin absorption regions of the semiconductor absorption substrate to twice the thickness of the pattern of thick and thin absorption regions of the stressor layer.

5. The method of claim 4, wherein the semiconductor absorption substrate includes a p-type semiconductor and the semiconductor emitter layer includes an n-type semiconductor.

6. The method of claim 4, wherein the metallurgy is a plurality of metallic fingers or bus contacts.

7. The method of claim 4, wherein the thick absorption regions are each 20-70 microns thick and the thin absorption regions are each 0-20 microns thick.

8. The method of claim 4, wherein the thick absorption regions are each at least five times as thick as each of the thin absorption regions.

9. The method of claim 4, wherein the plurality of thin absorption regions are sufficiently thin to render the semiconductor substrate flexible.

10. (canceled)

11. The method of claim 4, wherein an antireflective coating is disposed over the semiconductor emitter layer.

12. The method of claim 4, wherein the step of applying the backing layer to the bottom surface of the spalled semiconductor absorption substrate includes disposing an aluminum layer to the bottom surface of the spalled semiconductor absorption substrate.

13. The method of claim 12, wherein the aluminum layer is disposed in blanket contact with the bottom surface of the spalled semiconductor absorption substrate.

14. The method of claim 12, wherein the aluminum layer is in contact with the bottom surface of the spalled semiconductor absorption substrate between a pattern of dielectric reflectors.

15. The method of claim 12, wherein a back-surface-field layer is disposed between the bottom surface of the spalled semiconductor absorption substrate and the aluminum layer.

16. The method of claim 12, wherein an insulating tape carrier is disposed under the aluminum layer.

17. The method of claim 4, wherein applying a stressor layer onto the adhesion layer or seed layer includes:
sputtering a first nickel layer on the adhesion layer or seed layer;
plating a second nickel layer on the sputtered nickel layer or seed layer;
disposing a resist pattern on the second nickel layer or seed layer;
plating a third nickel layer on the second nickel layer through the resist pattern; and
removing the resist pattern.

18. The method of claim 4, wherein the stressor layer has a tensile stress of greater than 100 megapascals.

19. A method for forming a mixed thickness substrate, comprising:
disposing an adhesion layer or a seed layer on a bottom surface of a semiconductor substrate;
sputtering a first nickel layer on the adhesion layer or seed layer;
plating a second nickel layer on the sputtered nickel layer or seed layer;
disposing a resist pattern on the second nickel layer or seed layer;
plating a third nickel layer on the second nickel layer through the resist pattern such that the third nickel layer has a pattern of thick and thin regions;
removing the resist pattern; and
spalling the semiconductor substrate such that a pattern of thick and thin regions corresponding to the arrangement of the third nickel layer disposed through the resist pattern are formed therefrom,
wherein the third nickel layer is configured to spall the pattern of thick and thin regions of the semiconductor substrate to twice the thickness of the pattern of thick and thin regions of the stressor layer.

20. The method of claim 19, wherein the plurality of thin absorption regions are sufficiently thin to render the semiconductor substrate flexible.
